(19) United States
(12) Patent Application Publication
(10) Pub. No.: US 2016/0349493 A1
(43) Pub. Date: Dec. 1, 2016

(54) SCANNING UNIT, LASER SCANNING MICROSCOPE, AND TEMPERATURE ADJUSTMENT METHOD

(71) Applicant: Sony Corporation, Tokyo (JP)

(72) Inventors: Takeshi MATSUI, Tokyo (JP); Masaaki HARA, Tokyo (JP); Yoshiki OKAMOTO, Kanagawa (JP); Kenji TANAKA, Tokyo (JP); Fumisada MAEDA, Tokyo (JP); Koichiro KISHIMA, Kanagawa (JP)

(21) Appl. No.: 15/117,252

(22) PCT Filed: Dec. 26, 2014
(86) PCT No.: PCT/JP2014/006516

§ 371 Date: Aug. 8, 2016

(30) Foreign Application Priority Data
Feb. 17, 2014 (JP) 2014-027873

(51) Int. Cl. G02B 21/00; G02B 7/00; H01S 5/024; G02B 26/10

(52) U.S. Cl. CPC G02B 21/0036; G02B 26/10; G02B 7/008; H01S 5/02438

(57) ABSTRACT

There is provided a scanning unit including a first base provided with a scanning mechanism at least having a laser light source that emits laser light of a predetermined wavelength and a scanner that scans a scanned body by using the laser light, a second base that is located at a surface of the first base opposite a surface thereof provided with the scanning mechanism and that is thermally separated from the first base; and a temperature adjustment mechanism that is provided between the first base and the second base and that adjusts a temperature of the scanning mechanism.

### CROSS REFERENCE TO RELATED APPLICATIONS

This application claims the benefit of Japanese Priority Patent Application JP 2014-027873 filed Feb. 17, 2014, the entire contents of which are incorporated herein by reference.

### TECHNICAL FIELD

The present disclosure relates to scanning units, laser scanning microscopes, and temperature adjustment methods.

### BACKGROUND ART

In recent years, the development of optical technologies and the development of semiconductor technologies are advancing, and there have been proposed various types of laser scanning microscopes, such as laser scanning microscopes that use various types of lasers, for example, semiconductor lasers, and laser scanning fluorescence microscopes that use laser light as excitation light.

For example, PTL 1 below proposes a laser scanning microscope in which a laser light source and a scanning optical system are incorporated within the same housing.

### CITATION LIST

### Patent Literature

[PTL 1] JP 2004-29205A

### SUMMARY

### Technical Problem

However, in the case where the laser light source and the scanning optical system are incorporated within the same housing, as proposed in PTL 1 above, the laser light source and the scanning optical system, when driven, may possibly affect the properties of the microscope. Specifically, the more a laser light source that generates a large amount of heat is used as the laser light source, the larger the size of a cooling mechanism for cooling the generated heat becomes, resulting in an increase in size of the device. Moreover, the heat generated from the laser light source may also possibly affect optical-axis control of the scanning optical system provided within the same housing. On the other hand, heat generated from the scanning optical system may possibly affect the laser light source whose laser properties change in accordance with temperature.

Accordingly, there is a demand for a technology that allows for effective management of heat generated from the laser light source and the scanning optical system while achieving size reduction of a scanning mechanism including the laser light source and the scanning optical system.

The present disclosure proposes a scanning unit, a laser scanning microscope, and a temperature adjustment method that allow for effective management of heat generated from the laser light source and the scanning optical system while achieving size reduction of the scanning mechanism including the laser light source and the scanning optical system.

### Solution to Problem

According to an embodiment of the present disclosure, there is provided a scanning unit including a first base provided with a scanning mechanism at least having a laser light source that emits laser light of a predetermined wavelength and a scanner that scans a scanned body by using the laser light, a second base that is located at a surface of the first base opposite a surface thereof provided with the scanning mechanism and that is thermally separated from the first base; and a temperature adjustment mechanism that is provided between the first base and the second base and that adjusts a temperature of the scanning mechanism.

According to another embodiment of the present disclosure, there is provided a laser scanning microscope including a scanning unit that includes a first base, a second base, and a temperature adjustment mechanism, the first base being provided with a scanning mechanism at least having a laser light source that emits laser light of a predetermined wavelength and a scanner that scans a scanned body by using the laser light, the second base being located at a surface of the first base opposite a surface thereof provided with the scanning mechanism and being thermally separated from the first base, the temperature adjustment mechanism being provided between the first base and the second base and adjusting a temperature of the scanning mechanism, and a microscope unit at least having a focus optical system that focuses the laser light from the scanning unit onto the scanned body placed at a predetermined position, the microscope unit being thermally separated from the scanning unit.

According to another embodiment of the present disclosure, there is provided a temperature adjustment method including disposing a scanning mechanism on a first base and providing a second base at a surface of the first base opposite a surface thereof provided with the scanning mechanism, the scanning mechanism at least having a laser light source that emits laser light of a predetermined wavelength and a scanner that scans a scanned body by using the laser light, the second base being thermally separated from the first base, and adjusting a temperature of the scanning mechanism by using a temperature adjustment mechanism provided between the first base and the second base.

According to one or more of embodiments of the present disclosure, heat generated at the scanning mechanism at least having the laser light source and the scanner that are disposed on the first base is discharged from the scanning mechanism via the temperature adjustment mechanism and the second base.

### Advantageous Effects of Invention

According to one or more of embodiments of the present disclosure described above, heat generated from the laser light source and the scanning optical system can be effectively managed while size reduction of the scanning mechanism including the laser light source and the scanning optical system can be achieved.

The above-described advantage is not necessarily limitative. In addition to or in place of the above-described advantage, any of advantages described in this specification or another advantage obvious from this specification may be exhibited.

### BRIEF DESCRIPTION OF DRAWINGS

FIG. 1A is a top view schematically illustrating a laser scanning microscope equipped with a scanning unit according to a first embodiment of the present disclosure.

FIG. 1B is a side view schematically illustrating the scanning unit according to this embodiment.

FIG. 1C is a side view schematically illustrating the scanning unit according to this embodiment.

FIG. 2A schematically illustrates an example of a laser light source included in the scanning unit according to this embodiment.

FIG. 2B schematically illustrates an example of a laser light source included in the scanning unit according to this embodiment.

FIG. 2C schematically illustrates an example of a laser light source included in the scanning unit according to this embodiment.

FIG. 2D schematically illustrates an example of a laser light source included in the scanning unit according to this embodiment.

FIG. 3 schematically illustrates an example of temperature adjustment mechanisms according to this embodiment.

FIG. 4 schematically illustrates an example of the temperature adjustment mechanisms according to this embodiment.

FIG. 5A schematically illustrates an example of the temperature adjustment mechanisms according to this embodiment.

FIG. 5B schematically illustrates an example of the temperature adjustment mechanisms according to this embodiment.

FIG. 6 schematically illustrates another example of the scanning unit according to this embodiment.

FIG. 7 illustrates an arrangement method of the temperature adjustment mechanisms according to this embodiment.

FIG. 8 schematically illustrates an arrangement example of the temperature adjustment mechanisms according to this embodiment.

FIG. 9A schematically illustrates an arrangement example of the temperature adjustment mechanisms.

FIG. 9B schematically illustrates an arrangement example of the temperature adjustment mechanisms.

FIG. 10 is a perspective view illustrating an example of the laser scanning microscope equipped with the scanning unit according to this embodiment in detail.

FIG. 11 is a perspective view illustrating an example of the laser light source included in the scanning unit according to this embodiment in detail.

FIG. 12A schematically illustrates an optical system of the laser scanning microscope according to this embodiment.

FIG. 12B schematically illustrates an optical system of the laser scanning microscope according to this embodiment.

FIG. 13 is a graph illustrating the relationship between the air flow of an air-cooling fan and the heat discharging capability.

FIG. 14 illustrates an examination result of the heat discharging capability of the temperature adjustment mechanisms.

### DESCRIPTION OF EMBODIMENTS

Preferred embodiments of the present disclosure will be described below in detail with reference to the appended drawings. In this specification and the drawings, components having substantially identical functions will be given the same reference characters so as to omit redundant descriptions.

The description will proceed in the following order.

1. First Embodiment
1.1. Configuration Examples of Scanning Unit and Laser Scanning Microscope Equipped with Scanning Unit
1.2. Arrangement Method of Temperature adjustment mechanisms
1.3. Specific Examples of Laser Scanning Microscope Equipped with Scanning Unit

2. Conclusion

3. Practical Example

### First Embodiment

Configuration Examples of Scanning Unit and Laser Scanning Microscope Equipped with Scanning Unit

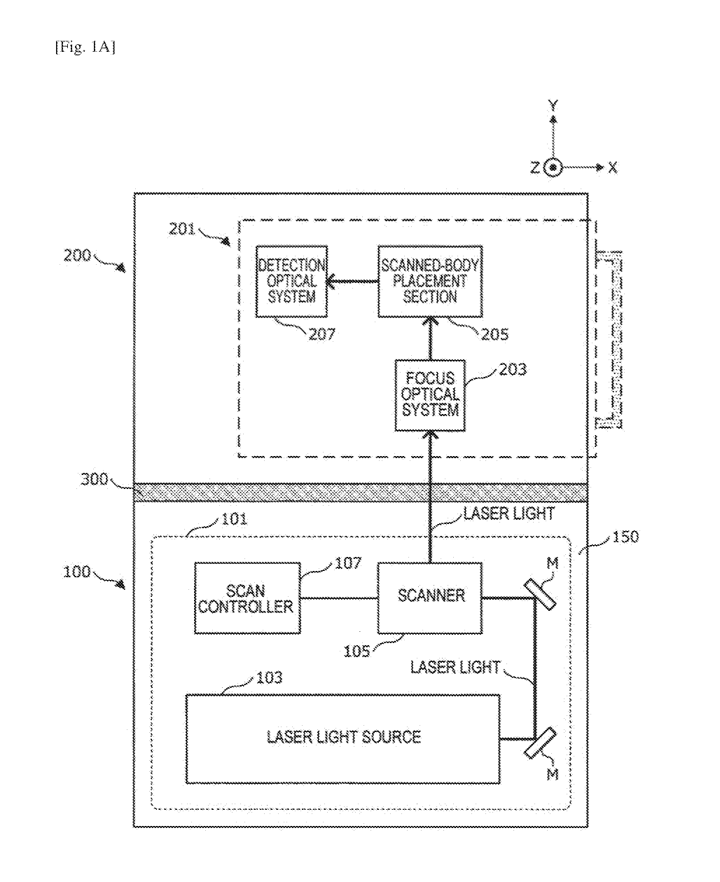

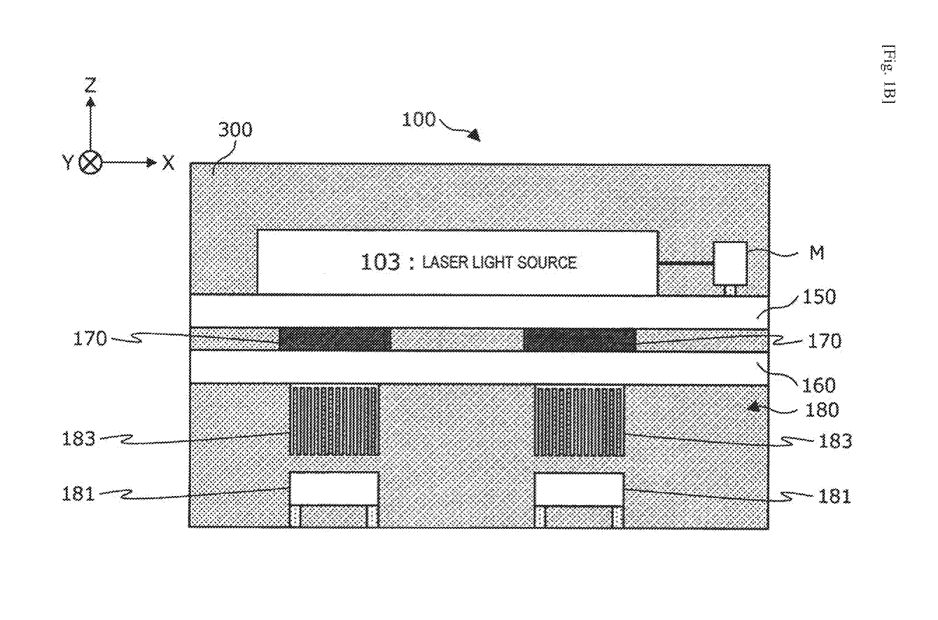

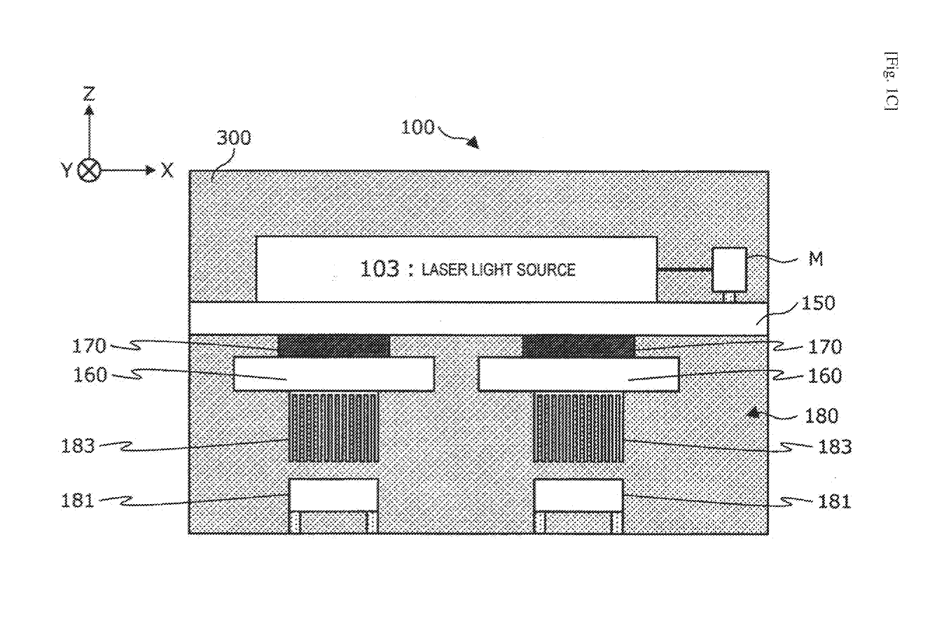

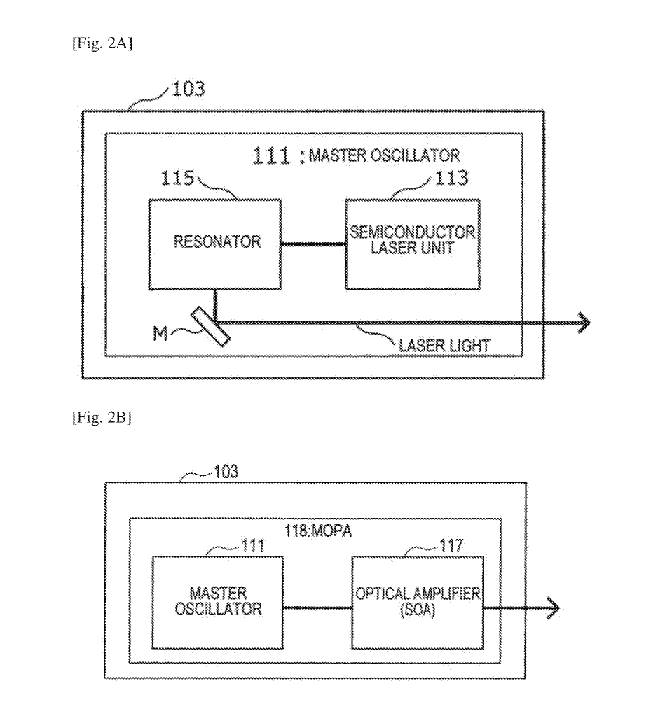

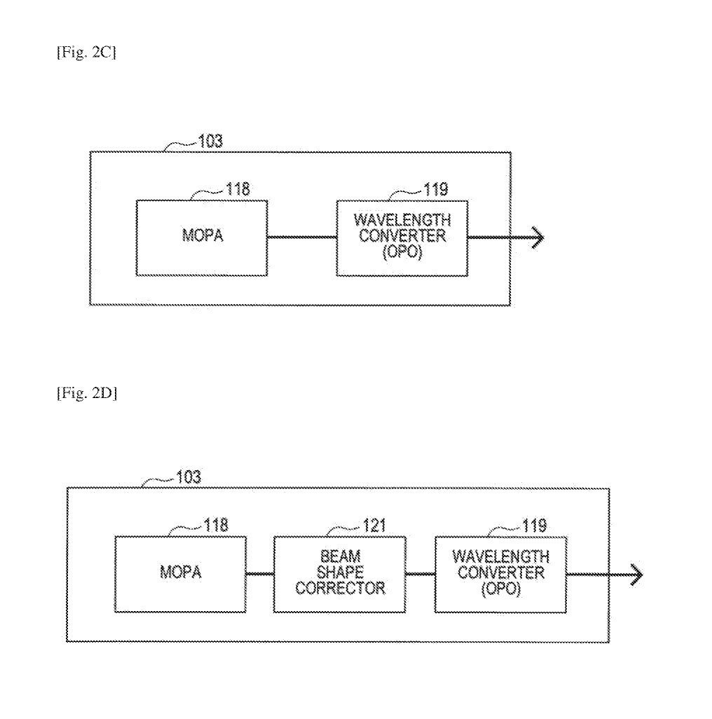

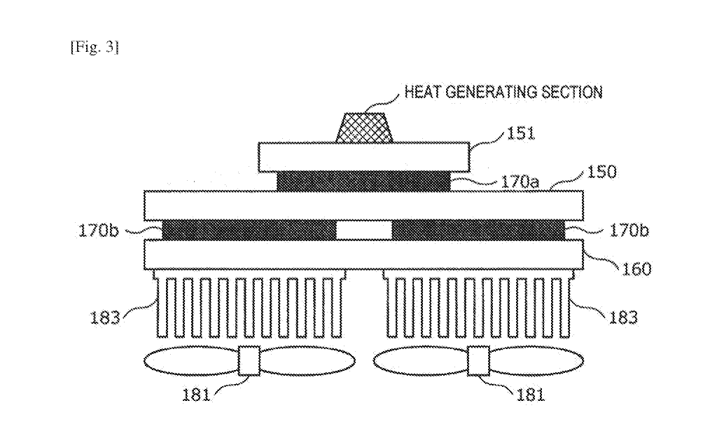

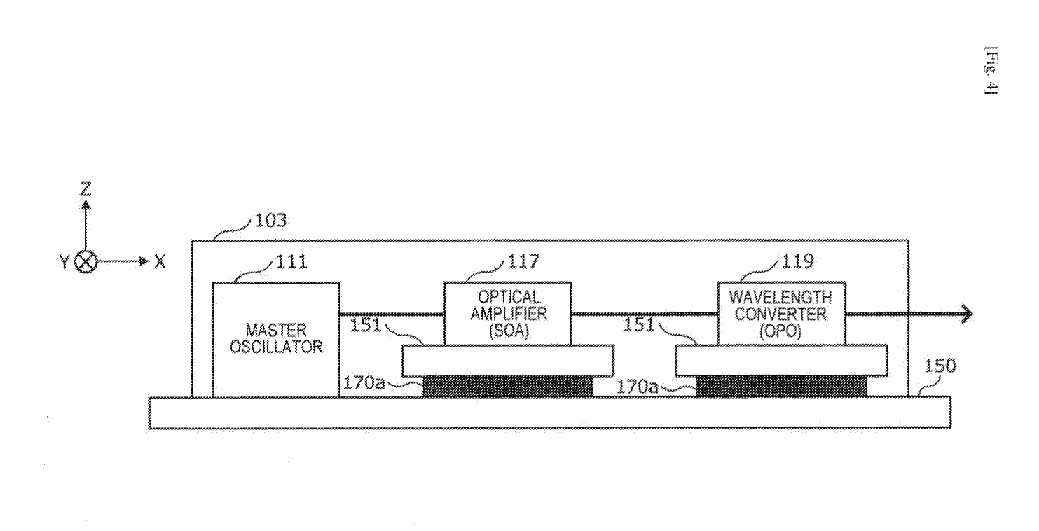

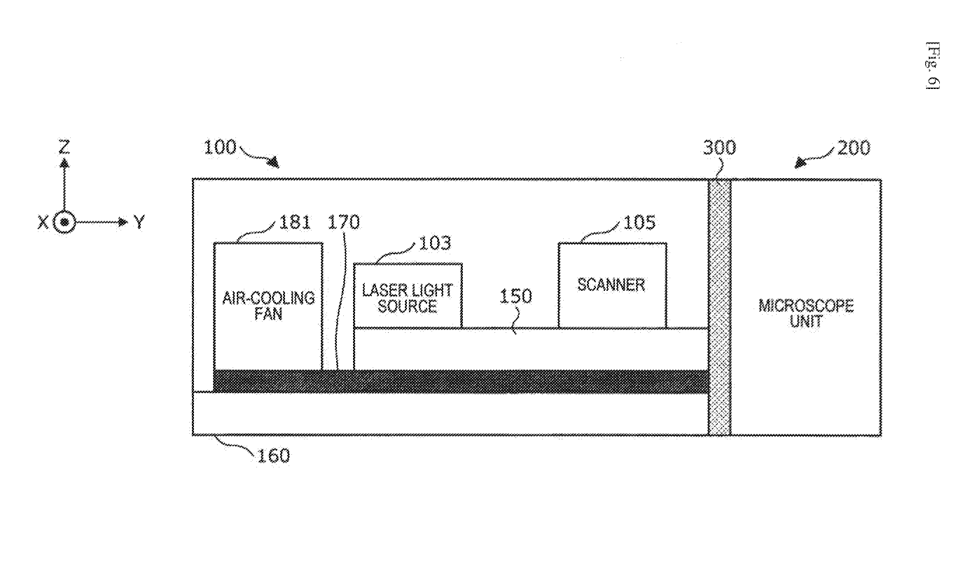

First, configuration examples of a scanning unit according to a first embodiment of the present disclosure and a laser scanning microscope equipped with the scanning unit will be described with reference to FIGS. 1A to 6. FIGS. 1A to 1C schematically illustrate the laser scanning microscope equipped with the scanning unit according to this embodiment. FIGS. 2A to 2D schematically illustrate an example of a laser light source included in the scanning unit according to this embodiment. FIGS. 3 to 5B schematically illustrate an example of temperature adjustment mechanisms according to this embodiment. FIG. 6 schematically illustrates another example of the scanning unit according to this embodiment.

The scanning unit and the laser scanning microscope according to this embodiment will be described below by appropriately using a coordinate system shown in each drawing.

FIG. 1A schematically illustrates an overall configuration example of a laser scanning microscope equipped with a scanning unit 100 according to this embodiment. As schematically shown in FIG. 1A, the laser scanning microscope according to this embodiment includes the scanning unit 100 according to this embodiment and a microscope unit 200. The scanning unit 100 and the microscope unit 200 are thermally separated from each other by a heat insulation wall 300.

The scanning unit 100 is a unit that scans laser light emitted from a light source so as to control an irradiation position of the laser light on a scanned body. As shown in FIG. 1A, the scanning unit 100 has a scanning mechanism 101 that scans laser light.

As schematically shown in FIG. 1A, the scanning mechanism 101 at least has a laser light source 103, a scanner 105, and a scan controller 107. Laser light emitted from the laser light source 103 is guided to the scanner 105 by various types of optical elements, such as steering mirrors M. The laser light scanned by the scanner 105 is guided to the microscope unit 200.

The laser light source 103 is configured to emit laser light of a predetermined wavelength. Although the type of laser provided as the laser light source 103 is not particularly limited, for example, a semiconductor laser may be preferably used. By using a semiconductor laser as a light source, the scanning unit 100 can be reduced in size, and the activation time of the scanning unit 100 can be shortened.

Examples of a semiconductor laser that can be used as the laser light source 103 include semiconductor lasers shown in FIGS. 2A to 2D.

FIG. 2A schematically illustrates a master oscillator 111, which is an example of a semiconductor laser applicable as the laser light source 103 and includes a semiconductor laser unit and a resonator. The master oscillator 111 provided as the laser light source 103 includes a semiconductor laser unit 113 that can emit laser light of a predetermined wavelength (e.g., a wavelength of 405 nm) and a resonator 115 for amplifying the laser light emitted from the semiconductor laser unit 113.

FIG. 2B schematically illustrates a master oscillator power amplifier (MOPA) 118, which is an example of a semiconductor laser applicable as the laser light source 103 and includes a master oscillator and an optical amplifier. In this light source, an optical amplifier 117 for further amplifying the emitted laser light is provided at a subsequent stage of the master oscillator 111 shown in FIG. 2A. A preferred example of the optical amplifier 117 is a semiconductor optical amplifier (SOA).

FIG. 2C schematically illustrates a light source, which is an example of a semiconductor laser applicable as the laser light source 103 and has a MOPA 118 and a wavelength converter. In this light source, a wavelength converter 119 for converting the wavelength of laser light whose intensity has been amplified is provided at a subsequent stage of the MOPA 118 shown in FIG. 2B. A preferred example of the wavelength converter 119 is an optical parametric oscillator (OPO) in which one of various types of nonlinear crystals is used. Furthermore, as shown in FIG. 2D, a beam shape corrector 121 that corrects the beam shape of the laser light may be provided between the MOPA 118 and the wavelength converter 119 so as to further enhance the wavelength conversion efficiency in the wavelength converter 119.

The laser light emitted from the laser light source 103 is guided to the scanner 105 via optical elements, such as the steering mirrors M and various types of lenses. The scanner 105 scans the laser light emitted from the laser light source 103 in a YZ direction in the drawing and controls, for example, the irradiation position of the laser light on the scanned body placed within the microscope unit 200. For example, the scanner 105 is constituted of one of various types of scanning mechanisms, such as a galvanometer scanning system (galvanometer mirror). Furthermore, the scanner 105 is controlled by the scan controller 107, such as a galvanometer scan driver, and performs scanning of the laser light under the control of the scan controller 107.

The scanning mechanism 101 at least including the laser light source 103, the scanner 105, and the scan controller 107 is disposed on a base plate 150, which is an example of a first base.

Needless to say, the scanning mechanism 101 according to this embodiment may have various types of mechanisms in addition to the laser light source 103, the scanner 105, and the scan controller 107 described above.

The laser light source 103 (particularly, the optical amplifier 117 and the wavelength converter 119), the scanner 105, and the scan controller 107 included in the scanning mechanism 101 generate heat when the scanning unit 100 is driven. Since there is a high possibility that the laser light source 103, the scanner 105, and the scan controller 107 may be variously affected by the heat generated from these mechanisms, it is preferable that the generated heat be appropriately discharged outward from the unit. The scanning unit 100 according to this embodiment is provided with a heat discharging mechanism to be described below so that the heat generated at the scanning mechanism 101 is appropriately discharged outward from the unit.

The heat discharging mechanism provided in the scanning unit 100 (in other words, a temperature management mechanism for managing the temperature of the scanning unit 100) will be described again later in detail.

The microscope unit 200 is an example of a scanned-body placement unit in which the scanned body is placed. The microscope unit 200 is provided with an opening 201 covered with an openable-closable lid (not shown), and at least a focus optical system 203 that focuses the laser light from the scanning unit 100 onto the scanned body is provided within the opening 201. Furthermore, a scanned-body placement section 205, such as an XY stage, on which the scanned body is placed and a detection optical system 207 at least having a detector for detecting various kinds of light reflected by and transmitted through the scanned body may be provided within the opening 201.

The focus optical system 203, the scanned-body placement section 205, the detection optical system 207, and so on provided in the microscope unit 200 are not particularly limited, and an arbitrary optical system, a sample placement mechanism, a detector, and so on may be appropriately used.

Although the example shown in FIG. 1A relates to a case where the detection optical system 207 including the detector is provided within the microscope unit 200, the detection optical system 207 may be provided in the scanning unit 100 or may be provided astride both the scanning unit 100 and the microscope unit 200. For example, if a photomultiplier tube (PMT) is used as the detector provided in the detection optical system 207, the photomultiplier tube is preferably disposed on the base plate 150 of the scanning unit 100. With regard to the photomultiplier tube, there is a possibility that a detection signal may have noise superposed thereon depending on the temperature of the environment in which the photomultiplier tube is provided. By providing the photomultiplier tube in the scanning unit 100, temperature adjustment can be appropriately performed, whereby the signal-to-noise (SN) ratio of the detection signal can be further improved.

The heat insulation wall 300 for preventing heat generated at the scanning unit 100 from being conducted to the microscope unit 200 is not particularly limited and may be formed by using a known heat insulation material.

Next, the heat discharging mechanism (temperature management mechanism) included in the scanning unit 100 according to this embodiment will be described in detail with reference to FIGS. 1B and 1C.

As previously described, the laser light source 103 (particularly, the semiconductor laser unit 113, the optical amplifier 117, and the wavelength converter 119), the galvanometer mirror of the scanner 105, the galvanometer scan driver of the scan controller 107, and so on that are included in the scanning mechanism 101 generate heat when driven. Therefore, in order to achieve stable operation of the scanning unit 100, it is preferable to provide a mechanism that appropriately discharges the heat generated from these mechanisms outward from the unit.

For example, as shown in FIG. 1 B, in order to appropriately discharge the heat generated at the scanning mechanism 101 outward from the unit, the scanning unit 100 according to this embodiment includes the base plate 150, a heat base 160, which is an example of a second base, and temperature adjustment mechanisms 170.

As shown in FIG. 1B, the scanning mechanism 101 is disposed on a surface of the base plate 150 at the positive side of the Z axis. The base plate 150 stably holds the scanning mechanism 101 and also efficiently conducts the heat generated at the scanning mechanism 101 toward the temperature adjustment mechanisms 170 and the heat base 160, which will be described later. As shown in FIGS. 1A and 1B, the base plate 150 is preferably formed of a single substrate. Although the material of the substrate constituting the base plate 150 is not particularly limited so long as it has high thermal conductivity, for example, copper, brass, or aluminum may be used. In particular, copper is preferably used. Furthermore, although the base plate 150 is preferably composed of a single material, the base plate 150 may be formed by joining together a plurality of substrates composed of a certain material. In view of corrosion resistance, the various kinds of metals that can be used for the base plate 150 may be given various kinds of coating or plating with high thermal conductivity (e.g., nickel-containing coating or electroless nickel plating).

In the scanning unit 100 according to this embodiment, the base plate 150 formed of a single substrate is used so that thermal design of the scanning mechanism 101 provided on the base plate 150 can be readily performed, whereby heat in the scanning mechanism 101 can be efficiently managed.

As shown in FIG. 1B, a surface of the base plate 150 opposite the surface thereof on which the scanning mechanism 101 is disposed (i.e., a surface at the negative side of the Z axis in FIG. 1B) is provided with the heat base 160. The base plate 150 and the heat base 160 are thermally separated from each other by the temperature adjustment mechanisms 170 provided between the base plate 150 and the heat base 160. Furthermore, a surface of the heat base 160 opposite a surface thereof facing the base plate 150 (i.e., a surface at the negative side of the Z axis in FIG. 1B) is provided with a heat discharger 180 that discharges the heat from the scanning mechanism 101 outward from the unit.

The heat base 160 efficiently conducts the heat discharged from the base plate 150 by the temperature adjustment mechanisms 170, which will be described later, toward the heat discharger 180. Similar to the base plate 150, a material of a substrate constituting the heat base 160 is preferably a material with high thermal conductivity, such as copper, brass, or aluminum. In particular, copper is preferably used. Furthermore, in view of corrosion resistance, the various kinds of metals that can be used for the heat base 160 may be given various kinds of coating or plating with high thermal conductivity (e.g., nickel-containing coating or electroless nickel plating).

The heat base 160 may be provided as a single substrate, as shown in FIG. 1B, or may be divided into a plurality of substrates, as shown in FIG. 1C.

The base plate 150 and the heat base 160 described above are fixed to the scanning unit 100 or to a frame (not shown) of the laser scanning microscope. The frame is not particularly limited and may be composed of a freely-chosen material so long as it can withstand load from the entire base plate 150 and the entire heat base 160. For example, such a material may be one of various kinds of metals, such as aluminum, iron, and stainless steel.

The temperature adjustment mechanisms 170 are provided between the base plate 150 and the heat base 160 and are configured to discharge the heat generated at the scanning mechanism 101 and also to adjust the temperature of the scanning mechanism 101. The temperature adjustment mechanisms 170 are preferably provided at positions below components acting as heat sources in the scanning mechanism 101 via the base plate 150. If an effect from a certain heat source extends over a wide range, a plurality of temperature adjustment mechanisms 170 for one heat source may be provided below the noteworthy heat source. By providing the temperature adjustment mechanisms 170, the heat generated at the scanning mechanism 101 can be efficiently conducted to the heat base 160.

The temperature adjustment mechanisms 170 are not particularly limited, and various known types of temperature adjustment units may be used. Examples of such temperature adjustment units include Peltier elements, heat pipes, and thermal conductive sheets. In the scanning unit 100 according to this embodiment, one of the aforementioned temperature adjustment units may be used, or a plurality of types of temperature adjustment units may be used in combination with each other.

A method of how the temperature adjustment mechanisms 170 are arranged relative to the heat sources will be described again later in detail.

As previously described, the heat discharger 180 that discharges the heat discharged from the scanning mechanism 101 by the temperature adjustment mechanisms 170 and the heat base 160 outward from the unit is provided below the heat base 160 (i.e., at the negative side of the Z axis). As shown in FIGS. 1B and 1C, this heat discharger 180 at least has air-cooling fans 181 for discharging the heat outside (i.e., an external space of the device) from a space (FIG. 1B) located below the heat base 160 or from a space (FIG. 1C) located below the base plate 150.

Furthermore, as shown in FIGS. 1B and 1C, in order to further ensure the discharging of the heat from the scanning mechanism 101, it is preferable that the heat discharger 180 further have heat sinks 183 that are disposed at the heat base 160 and that dissipate the discharged heat. With the heat discharger 180 having both the air-cooling fans 181 and the heat sinks 183, the heat sinks 183 can efficiently dissipate the heat discharged from the scanning mechanism 101 by the temperature adjustment mechanisms 170 and the heat base 160, and the air-cooling fans 181 can more efficiently discharge the heat dissipated by the heat sinks 183 outward from the unit.

The air-cooling fans 181 used in the heat discharger 180 according to this embodiment are not particularly limited, and freely-chosen air-cooling fans 181 may be used. Furthermore, fans that utilize mechanisms other than air-cooling mechanisms may also be used.

Similar to the base plate 150 and the heat base 160, a material of a substrate constituting each heat sink 183 is preferably a material with high thermal conductivity, such as copper, brass, or aluminum. In particular, copper is preferably used. Furthermore, in view of corrosion resistance, the various kinds of metals that can be used for each heat sink 183 may be given various kinds of coating or plating with high thermal conductivity (e.g., nickel-containing coating or electroless nickel plating).

Although the sizes of the air-cooling fans 181 and the heat sinks 183 are not particularly limited, it is preferable that the air-cooling fans 181 and the heat sinks 183 be as large as possible. This is because the heat discharging capability of the air-cooling fans 181 and the heat discharging capability of the heat sinks 183 improve with increasing sizes thereof. Although it is possible to use relatively small-sized air-cooling fans 181 and relatively small-sized heat sinks 183, if the scanning unit 100 including the heat discharger 180 is to be used in combination with the microscope unit 200, it is preferable that a more detailed examination be performed. In order to increase the heat discharging capability by using relatively small-sized air-cooling fans 181, it is demanded that the air flow be increased by increasing the rotation speed if the fan diameter is the same. On the other hand, since an increase in rotation speed of the fans leads to an increase in noise and vibration, if the scanned body is observed with a large enlargement ratio as in the microscope unit 200, the vibration caused by the increased rotation speed has a large effect.

The configuration of the scanning unit 100 according to this embodiment and the configuration of the laser scanning microscope equipped with the scanning unit 100 have been described above in detail with reference to FIGS. 1A to 2D. Modifications of Temperature adjustment mechanisms

When adjusting the temperature of the scanning mechanism 101 by using the temperature adjustment mechanisms 170, it is conceivable that the amount of heat discharged from the scanning mechanism 101 may be large relative to the size of the temperature adjustment mechanisms 170. In this case, as shown in FIG. 3, a plurality of temperature adjustment mechanisms 170 may be disposed in a stacked fashion in a direction extending from the base plate 150 toward the heat base 160 (i.e., Z-axis direction in FIGS. 1B and 1C).

In the example shown in FIG. 3, when disposing a certain heat generating section onto the base plate 150, the heat generating section is temporarily disposed on a sub base plate 151, and a first temperature adjustment mechanism 170a is disposed below the sub base plate 151. Then, the first temperature adjustment mechanism 170a may be disposed on the base plate 150, and second temperature adjustment mechanisms 170b may be disposed below the base plate 150, as shown in FIGS. 1B and 1C.

By stacking the plurality of temperature adjustment mechanisms 170 in the Z-axis direction in this manner, even when the noteworthy heat generating section (heat source) generates a larger amount of heat, the heat can be discharged more efficiently.

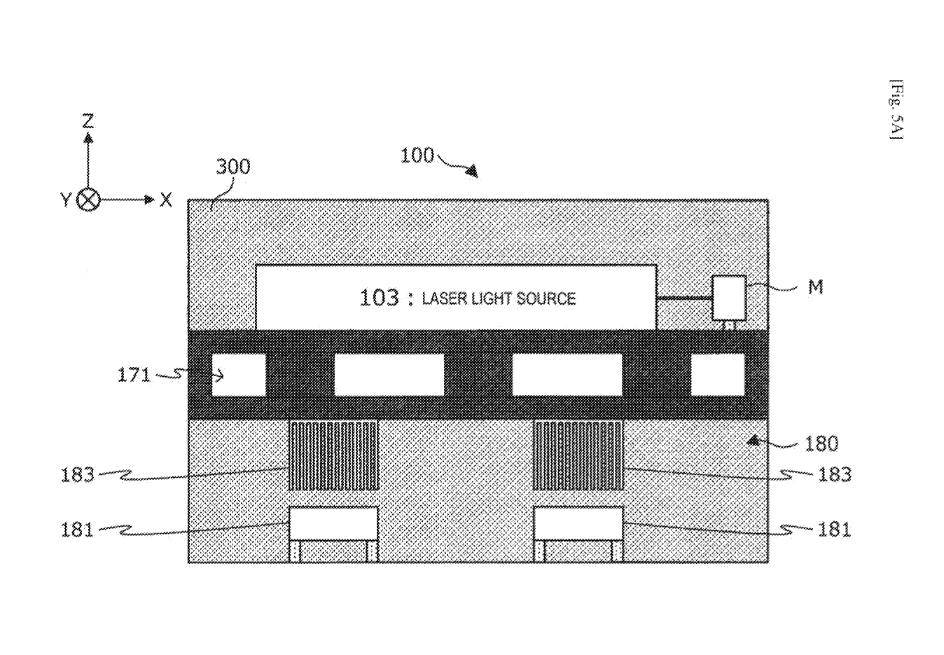

The method of arranging the temperature adjustment mechanisms 170 at multiple levels as shown in FIG. 3 is suitable when, for example, disposing the laser light source 103 onto the base plate 150, as shown in FIG. 4. If one of the semiconductor lasers shown in FIGS. 2B to 2D is used as a laser light source, it is particularly important to manage heat generated from the optical amplifier 117 as well as heat generated from the wavelength converter 119 for correcting temporal changes in laser properties and maintaining stable laser oscillation. By using the temperature adjustment mechanisms 170 at multiple levels as shown in FIG. 3, the heat generated from these heat sources can be released outward from the unit by being conducted efficiently in the following order: the base plate 150, the temperature adjustment mechanisms 170, and the heat base 160.

The configuration provided with the temperature adjustment mechanisms 170 at multiple levels as shown in FIGS. 3 and 4 can be used when, for example, disposing the scanner 105 or the scan controller 107 onto the base plate 150 instead of disposing the laser light source 103 onto the base plate 150.

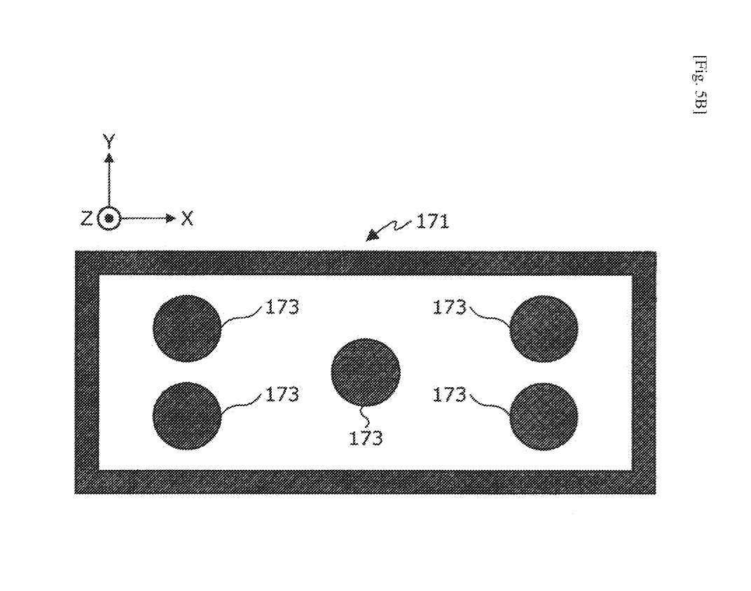

Furthermore, although the base plate 150, the heat base 160, and the temperature adjustment mechanisms 170 are shown as separate components in, for example, FIG. 1B, these components may alternatively be formed by integrally molding a base by using a thin flat heat pipe (vapor chamber) 171, as shown in FIGS. 5A and 5B. As shown in FIGS. 5A and 5B, with regard to this thin flat heat pipe 171, two base substrates are disposed facing each other with a plurality of cylindrical columns 173 interposed therebetween.

Furthermore, if a heat pipe is to be used as a temperature adjustment mechanism 170, for example, as shown in FIG. 6, an air-cooling fan 181 constituting the heat discharger 180 may be disposed beside the base plate 150 (e.g., at a side thereof in the Y-axis direction) so that size reduction of the device (particularly, size reduction in the height direction) may be achieved.

The modifications of the temperature adjustment mechanisms 170 according to this embodiment have been briefly described above with reference to FIGS. 3 to 6.

Arrangement Method of Temperature Adjustment Mechanisms

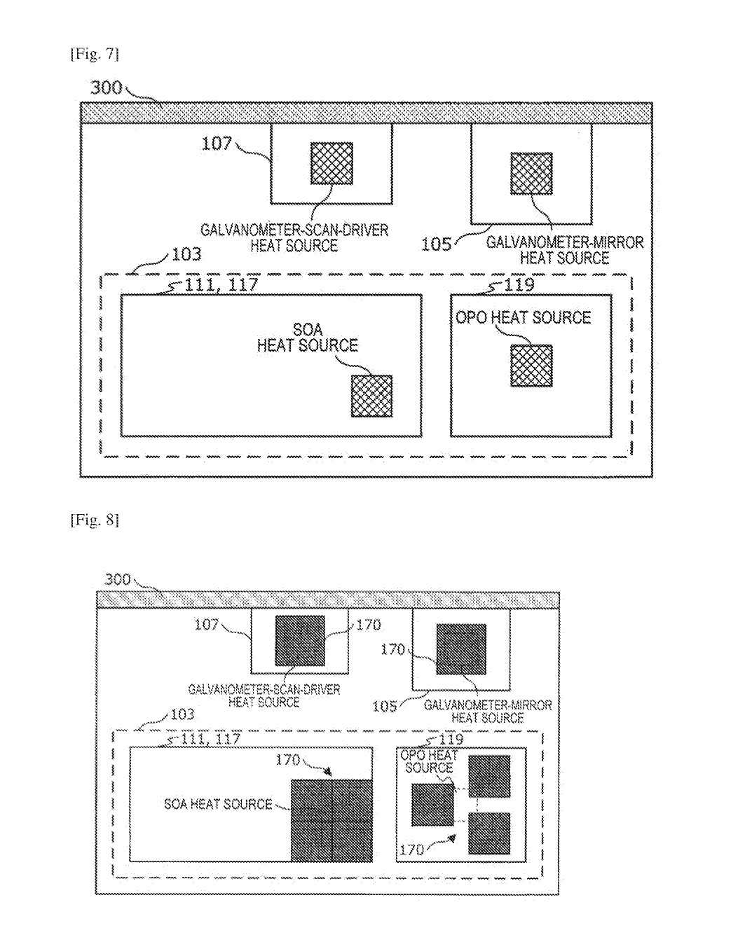

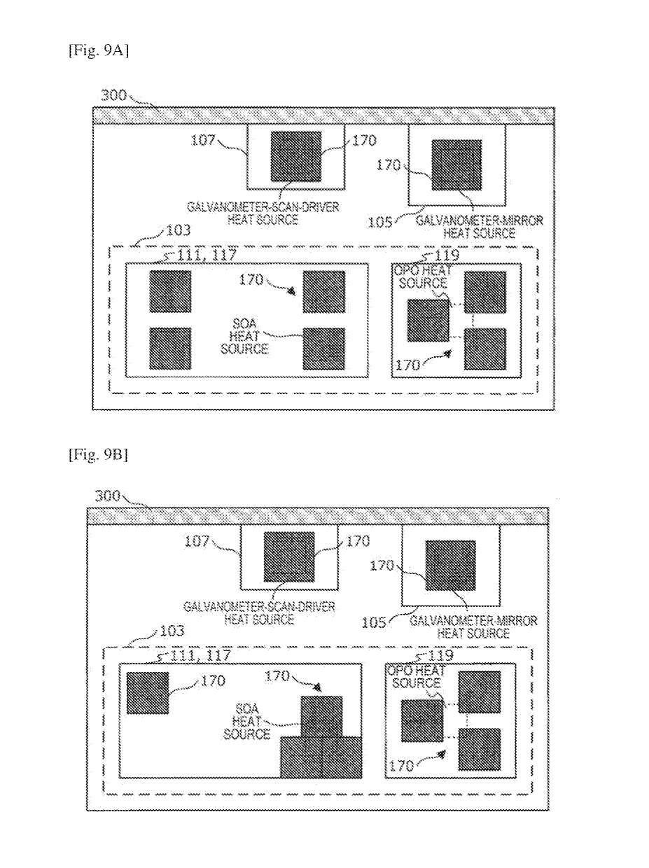

Next, an arrangement method of the temperature adjustment mechanisms 170 according to this embodiment will be described with reference to FIGS. 7 to 9B. FIG. 7 illustrates the arrangement method of the temperature adjustment mechanisms 170 according to this embodiment, and FIG. 8 schematically illustrates an arrangement example of the temperature adjustment mechanisms 170 according to this embodiment. FIGS. 9A and 9B schematically illustrate other arrangement examples of the temperature adjustment mechanisms 170 according to this embodiment.

As shown in FIG. 7, in the following description, it is assumed that two heat sources (i.e., an SOA heat source and an OPO heat source) exist in the laser light source 103, a heat source resulting from the galvanometer mirror (i.e., a galvanometer-mirror heat source) exists in the scanner 105, and a heat source resulting from the galvanometer scan driver (i.e., a galvanometer-scan-driver heat source) exists in the scan controller 107. The positions of the respective heat sources are positions shown in FIG. 7.

As previously described, the temperature adjustment mechanisms 170 according to this embodiment may be disposed below noteworthy heat sources. Therefore, if the amount of heat generated from a heat source can be handled with the heat discharging capability of a temperature adjustment mechanism 170, one temperature adjustment mechanism 170 for one heat source may be disposed below the noteworthy heat source. If it is difficult to handle the amount of heat generated from a heat source with the heat discharging capability of one temperature adjustment mechanism 170 or if precise temperature management has to be performed with respect to a noteworthy heat source, a plurality of temperature adjustment mechanisms 170 may be disposed for one heat source.

For example, as shown in FIG. 8, it is assumed that the amount of heat generated from the SOA heat source is large and precise temperature management has to be performed with respect to the wavelength converter (OPO) 119. In this case, if the amount of heat generated from each of the galvanometer-mirror heat source and the galvanometer-scan-driver heat source can be handled with the heat discharging capability of one temperature adjustment mechanism 170, one temperature adjustment mechanism 170 may be disposed below each of the galvanometer-mirror heat source and the galvanometer-scan-driver heat source, as shown in FIG. 8. Furthermore, as schematically shown in FIG. 8, in order to discharge the heat from each heat source more reliably, the installation area of the corresponding temperature adjustment mechanism 170 may be set to be larger than the area of the heat source.

Furthermore, with regard to the wavelength converter (OPO) 119 of the laser light source 103, it is assumed that the amount of heat generated from the heat source can be handled with the heat discharging capability of one temperature adjustment mechanism 170, but the wavelength converter 119 is a component for which precise temperature management has to be performed. In this case, as shown in FIG. 8, a plurality of temperature adjustment mechanisms 170 may be evenly arranged within a temperature management region in which precise temperature management is demanded. Thus, precise temperature management can be achieved.

If the amount of heat generated from a heat source is large, as in the optical amplifier (SOA) 117 of the laser light source 103, a plurality of temperature adjustment mechanisms 170 may be provided in a concentrated manner below the heat source from which a large amount of heat is discharged, as shown in FIG. 8. Thus, the temperature of the base plate 150 (in other words, a set temperature of the temperature adjustment mechanisms 170) can be set close to the ambient temperature (e.g., 25 degrees Celsius), whereby the heat discharging capability of the temperature adjustment mechanisms 170 can be enhanced. However, if the amount of heat generated from a heat source is large, as in the optical amplifier (SOA) 117, it is preferable that the set temperature of the temperature adjustment mechanisms 170 be set to be lower (e.g., 20 degrees Celsius) than the ambient temperature.

On the other hand, in the examples shown in FIGS. 9A and 9B, the arrangement positions of the temperature adjustment mechanisms 170 with respect to the optical amplifier (SOA) 117 that generates a large amount of heat are different from those in FIG. 8. If the temperature adjustment mechanisms 170 are evenly arranged regardless of the position of the SOA heat source, as shown in FIG. 9A, or if one temperature adjustment mechanism 170 is disposed away from the other temperature adjustment mechanisms 170 at a position not related to the heat source, as shown in FIG. 9B, temperature gradient occurs in the base plate 150. Temperature gradient increases with increasing amount of heat generated from the heat source and may induce, for example, condensation in accordance with, for example, the humidity condition within the housing of the device, possibly causing a problem in the device. Therefore, if possible, it is preferable that the arrangement of the temperature adjustment mechanisms 170 as shown in FIGS. 9A and 9B be avoided with respect to a heat source that generates a large amount of heat. If there is no choice but to arrange the temperature adjustment mechanisms 170 as shown in FIG. 9A or 9B due to other design limitations, it is preferable that airtightness within the scanning unit 100 be maintained as much as possible and that humidity be reduced as much as possible by using, for example, various kinds of desiccants.

The arrangement method of the temperature adjustment mechanisms 170 according to this embodiment has been described above with reference to FIGS. 8 to 9B.

Specific Examples of Laser Scanning Microscope Equipped with Scanning Unit

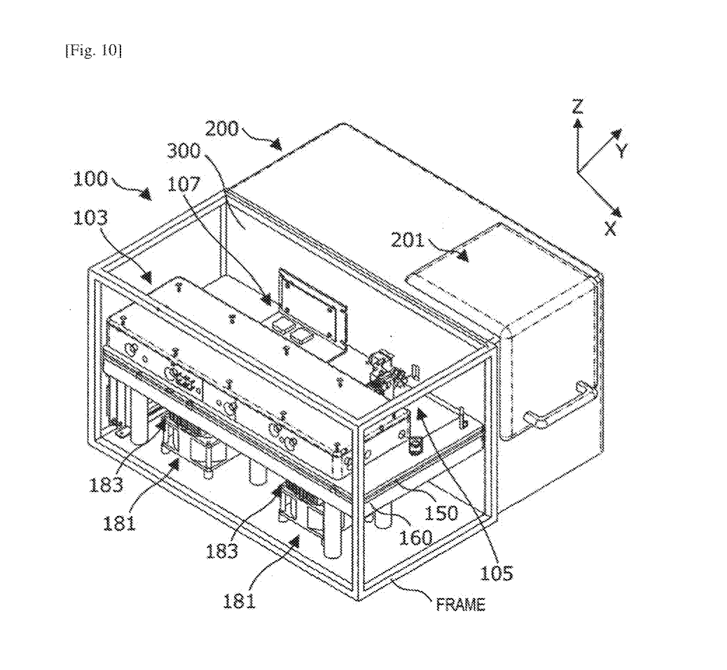

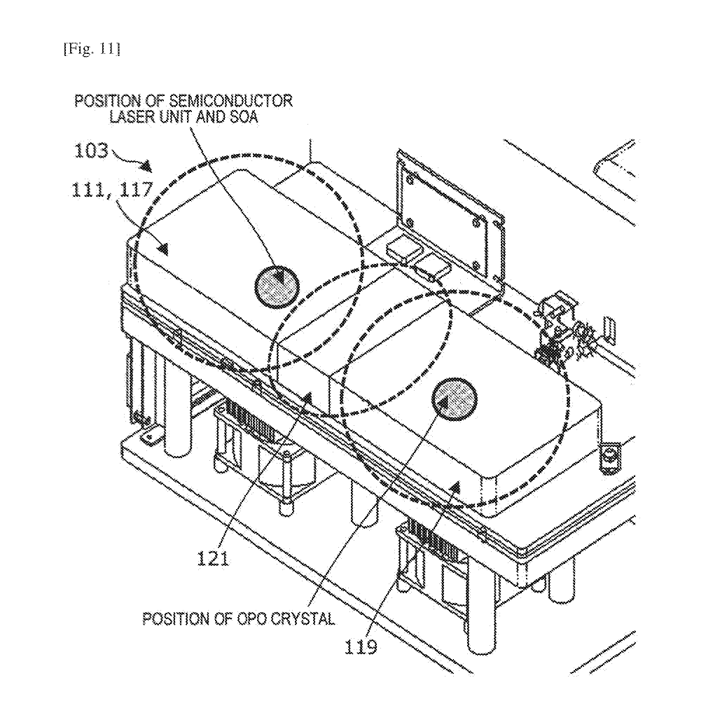

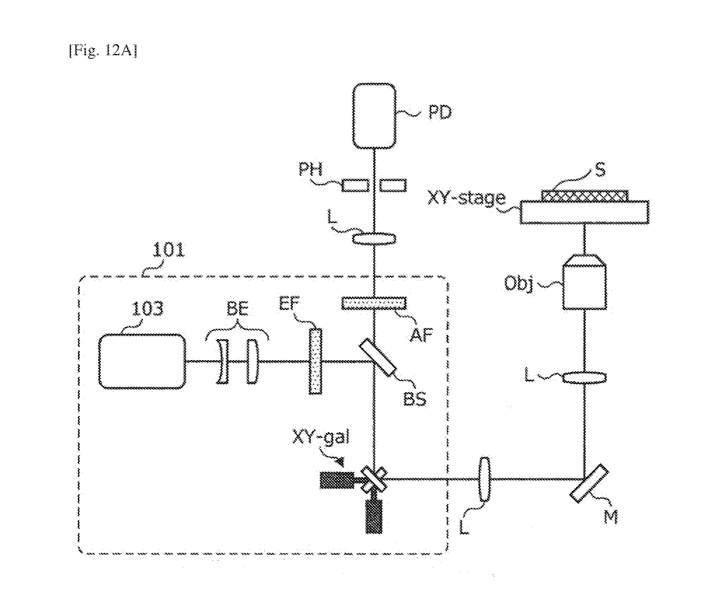

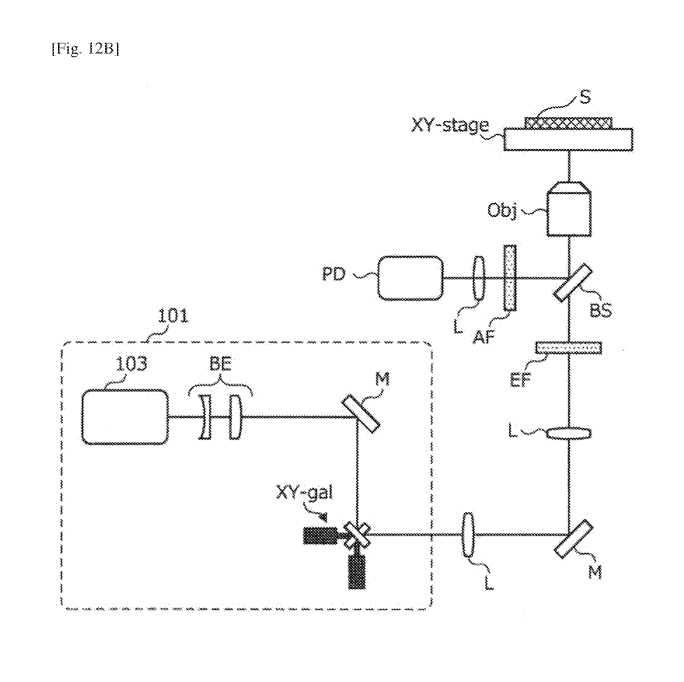

Next, specific examples of the laser scanning microscope equipped with the above-described scanning unit 100 will be briefly described with reference to FIGS. 10 to 12B. FIG. 10 is a perspective view illustrating an example of the laser scanning microscope equipped with the scanning unit 100 according to this embodiment in detail. FIG. 11 is a perspective view illustrating an example of the laser light source 103 included in the scanning unit 100 according to this embodiment in detail. FIGS. 12A and 12B schematically illustrate an optical system of the laser scanning microscope according to this embodiment.

As shown in FIG. 10, the laser scanning microscope has the above-described scanning unit 100 and the microscope unit 200. The scanning unit 100 and the microscope unit 200 are thermally separated from each other by the heat insulation wall 300.

The scanning unit 100 has the base plate 150, which is composed of copper and on which the scanning mechanism 101 at least having the laser light source 103, the scanner 105, and the scan controller 107 is disposed, and the heat base 160 composed of copper. A plurality of Peltier elements (not shown) as the aforementioned temperature adjustment mechanisms 170 are provided between the base plate 150 and the heat base 160. The base plate 150 and the heat base 160 are supported by a box-shaped frame as shown in FIG. 10.

The heat discharger 180 having the air-cooling fans 181 and the heat sinks 183 composed of copper is provided below the heat base 160.

As shown in FIG. 11, the laser light source 103 is constituted of a semiconductor laser having the master oscillator 111 that emits blue laser light with a wavelength of 405 nm, the optical amplifier 117, the wavelength converter 119, and the beam shape corrector 121. The semiconductor laser unit and the SOA, as well as the OPO crystal, which are heat sources, are substantially disposed at positions shown in FIG. 11. The plurality of temperature adjustment mechanisms 170 (i.e., Peltier elements) are arranged below these heat sources in accordance with the arrangement method described with reference to FIGS. 9A and 9B.

The microscope unit 200 is provided with the opening 201 covered with an openable-closable lid. The scanned-body placement section 205 at which a scanned body is placed and various types of optical systems constituting the microscope are installed within this opening 201.

Examples of the optical system of the laser scanning microscope shown in FIG. 10 will be briefly described with reference to FIGS. 12A and 12B. FIG. 12A schematically illustrates the optical system in a case where the laser scanning microscope shown in FIG. 10 is realized as a laser-scanning confocal microscope. FIG. 12B schematically illustrates the optical system in a case where the laser scanning microscope shown in FIG. 10 is realized as a laser-scanning fluorescence microscope (e.g., a two-photon excitation fluorescence microscope).

In the optical system of the confocal microscope shown in FIG. 12A, laser light emitted from the laser light source 103 is transmitted through a beam expander BE and an excitation filter EF and is subsequently guided to an XY galvanometer mirror (XY-gal) via a beam splitter BS. The irradiation position of the laser light is scanned by the XY galvanometer mirror, and the laser light is guided to an objective lens Obj via relay lenses L and a mirror M. The laser light transmitted through the objective lens Obj is radiated onto a scanned body S placed on an XY stage. An image of the scanned body S is transmitted through the objective lens Obj, the relay lenses L, the mirror M, the XY galvanometer mirror, and the beam splitter BS and is subsequently guided to an absorption filter AF. The image of the scanned body S transmitted through the absorption filter AF is transmitted through a relay lens L and a pinhole PH and is subsequently detected by a photo-detector PH, such as a PMT.

In the optical system of the fluorescence microscope shown in FIG. 12B, laser light emitted from the laser light source 103 travels through a beam expander BE and a mirror M and is guided to an XY galvanometer mirror (XY-gal). The irradiation position of the laser light is scanned by the XY galvanometer mirror, and the laser light travels through relay lenses L, a mirror M, an excitation filter EF, and a beam splitter BS and is guided to an objective lens Obj. The laser light transmitted through the objective lens Obj is radiated onto a scanned body S placed on an XY stage. Fluorescence generated from the scanned body S as a result of the laser light, which is excitation light, travels through the objective lens Obj and the beam splitter BS and is guided to an absorption filter AF. The fluorescence from the scanned body S transmitted through the absorption filter AF is transmitted through a relay lens L and is subsequently detected by a photo-detector PH, such as a PMT.

The specific examples of the laser scanning microscope having the scanning unit 100 according to this embodiment have been briefly described with reference to FIGS. 10 to 12B.

The specific examples of the laser scanning microscope described above are merely examples, and various modifications are conceivable, such as a configuration in which the optical system has a different configuration, different arrangement, or different arrangement order, a configuration in which the wavelength band of the laser light is different, or a configuration in which components that exhibit similar effects are used as the temperature adjustment mechanisms and the heat discharger.

Furthermore, in addition to the above-described laser scanning microscope, the scanning unit 100 according to this embodiment can be applied to any one of various types of devices in which scanning of laser light is demanded, such as a device that uses a laser light source for therapeutic purposes (e.g., a therapeutic laser device such as an ophthalmic laser device), a projection-type image display device that forms an expanded image by scanning laser light in X and Y directions (e.g., a projector or semiconductor image rendering device), and a laser processing device. Conclusion

As described above, in the scanning unit 100 according to the embodiment of the present disclosure, the laser light source and the scanning module are provided on the same base plate so that the heat sources are combined therewith, thereby achieving commonality of heat discharged from the laser light source and the scanning module. Thus, the heat release area of the heat generated by the heat sources can be increased, thereby allowing for highly efficient cooling. Furthermore, by combining the laser light source and the scanning module with each other, the positions of the laser light source and the scanning module can be readily optimized from the standpoint of heat and vibration. As a result, with air-cooling-based temperature adjustment, an auxiliary device, such as a chiller, does not have to be provided, and the overall size of the device can be reduced.

Furthermore, by combining the laser light source and the scanning module with each other, even when an optical fiber is used as a laser-light guiding section, the coupling efficiency with respect to the optical fiber can be prevented from decreasing, thereby allowing for efficient use of light as well as ease of maintenance.

### PRACTICAL EXAMPLE

Next, the scanning unit 100 according to the embodiment of the present disclosure will be described in detail with reference to a practical example. In the following practical example, the scanning unit 100 according to the embodiment of the present disclosure is merely an example. The scanning unit 100 according to the embodiment of the present disclosure is not to be limited to the following practical example.

First, the sizes of an air-cooling fan and a heat sink provided in the scanning unit 100, and the relationship between the air flow and the heat discharging capability are examined.

In this examination, the relationship between the air flow and the heat discharging capability is examined by using an air-cooling fan and a copper heat sink both having four 60-mm sides, an air-cooling fan and a copper heat sink both having four 80-mm sides, and an air-cooling fan and a copper heat sink both having four 120-mm sides.

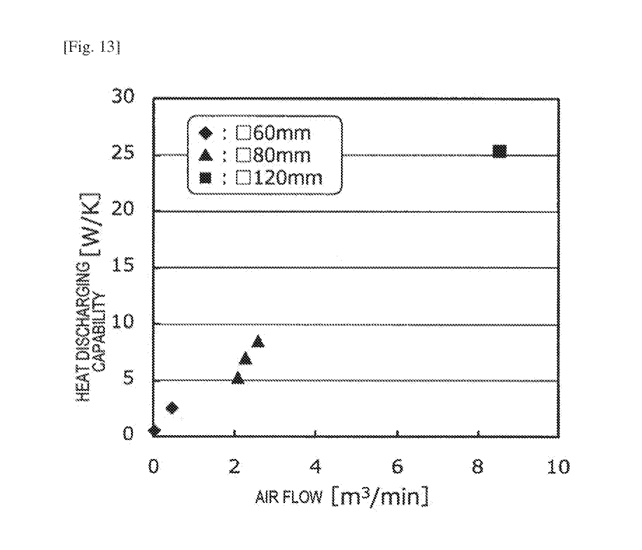

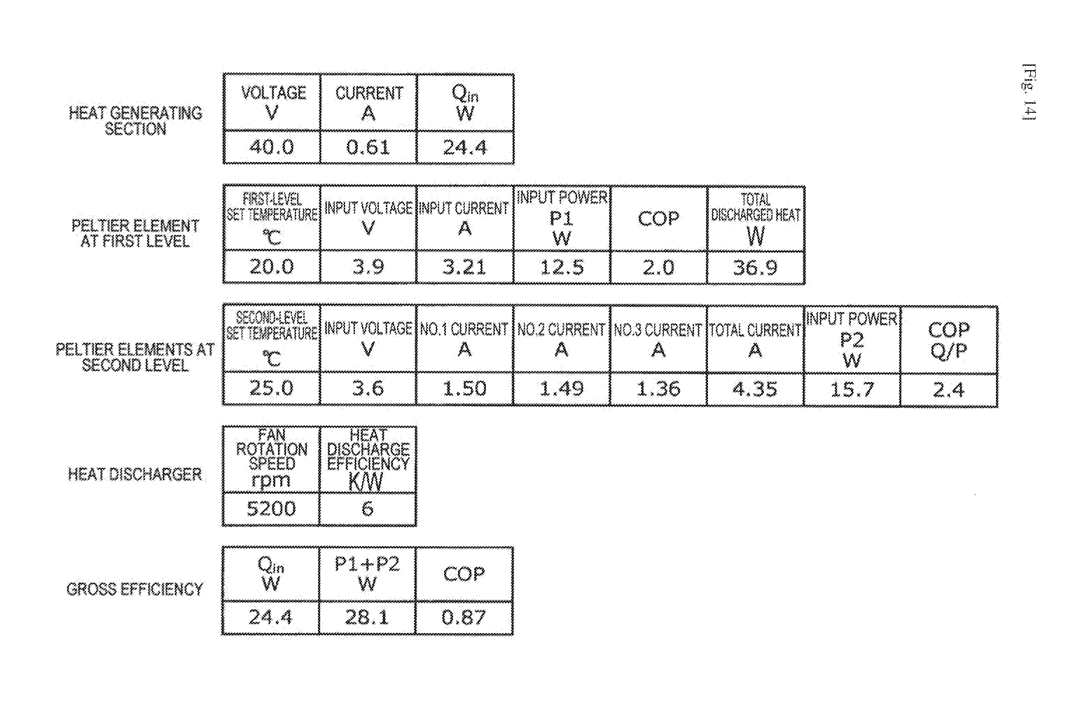

The obtained results are shown in FIG. 13.

It is clear from FIG. 13 that, with increasing size of the air-cooling fan, the air flow increases and the obtained heat discharging capability also increases. These results indicate that it is preferable that the sizes of the air-cooling fans 181 and the heat sinks 183 provided as the heat discharger 180 in the scanning unit 100 be as large as possible.

Next, the heat discharging capability is examined in a case where Peltier elements are used as the temperature adjustment mechanisms 170 and the temperature adjustment mechanisms 170 are stacked in the vertical direction as shown in FIG. 3. In this case, the number of Peltier elements at the first level provided below the heat generating section (SOA) is one, and the number of Peltier elements at the second level provided below the sub base plate 151 is three.

The amount of heat generated at the heat generating section, the set conditions of each Peltier element, and the details of the heat discharger 180 are as shown in FIG. 14.

In this examination, a heat value of 24.4 W generated by the SOA is heat-transported to the Peltier elements at the second level by using an electric power of 12.5 W input to the Peltier element at the first level. The Peltier elements at the second level discharge 36.9 W, which is the sum of the heat value of 24.4 W generated by the SOA and the electric power of 12.5 W input to the Peltier element at the first level. In this case, an electric power of about 5 W is input to each of the three Peltier elements so that the heat is transported toward the heat base 160. In this examination example, the heat can be discharged by using an air-cooling fan with a rotation speed of 5200 rpm.

As shown in a lower part of FIG. 14, with regard to gross efficiency in this examination, a total input electric power is 28.1 W relative to the heat value of 24.4 W, and a coefficient of performance (COP) is 0.87.

Although preferred embodiments of the present disclosure have been described above in detail with reference to the appended drawings, the technical scope of the present disclosure is not limited to the above examples. It should be understood by those with a general knowledge of the technical field of the present disclosure that various modifications or alterations may occur insofar as they are within the technical scope of the appended claims, and that these modifications or alterations are included in the technical scope of the present disclosure.

Furthermore, the advantages described in this specification are only intended for illustrative and exemplary purposes and are not limitative. In other words, in addition to or in place of the above-described advantages, the technology according to the embodiment of the present disclosure may exhibit other advantages that are obvious to a skilled person from the specification.

Additionally, the present technology may also be configured as below.

(1) A scanning unit including:
a first base provided with a scanning mechanism at least having a laser light source that emits laser light of a predetermined wavelength and a scanner that scans a scanned body by using the laser light;
a second base that is located at a surface of the first base opposite a surface thereof provided with the scanning mechanism and that is thermally separated from the first base; and
a temperature adjustment mechanism that is provided between the first base and the second base and that adjusts a temperature of the scanning mechanism.

(2) The scanning unit according to (1), wherein a surface of the second base opposite a surface thereof facing the first base is provided with a heat discharger that discharges heat discharged from the scanning mechanism by the temperature adjustment mechanism and the second base outward from the unit.

(3) The scanning unit according to (2), wherein the heat discharger at least has an air-cooling fan that discharges the discharged heat outward from the unit.

(4) The scanning unit according to (3), wherein the heat discharger further has a heat sink that is disposed at the second base and that dissipates the discharged heat, and wherein the air-cooling fan discharges the discharged heat dissipated by the heat sink outward from the unit.

(5) The scanning unit according to any one of (1) to (4), wherein a plurality of the temperature adjustment mechanisms are disposed in a stacked fashion in a direction extending from the first base toward the second base.

(6) The scanning unit according to any one of (1) to (5), wherein the scanning unit is connected to a scanned-body placement unit, in which the scanned body is placed, via a heat insulation wall composed of a predetermined heat insulation material.

(7) The scanning unit according to any one of (1) to (6), wherein the temperature adjustment mechanism is at least one of a Peltier element, a heat pipe, and a thermal conductive sheet.

(8) The scanning unit according to any one of (1) to (7), wherein the laser light source is a master oscillator having a semiconductor laser and a resonator.

(9) The scanning unit according to any one of (1) to (7), wherein the laser light source is a master oscillator power amplifier that includes a master oscillator and an optical amplifier, the master oscillator having a semiconductor laser and a resonator, the optical amplifier amplifying laser light from the master oscillator.

(10) The scanning unit according to any one of (1) to (7), wherein the laser light source is a light source that includes a master oscillator, an optical amplifier, and a wavelength converter, the master oscillator having a semiconductor laser and a resonator, the optical amplifier amplifying laser light from the master oscillator, the wavelength converter converting a wavelength of the amplified laser light.

(11) A laser scanning microscope including:
a scanning unit that includes a first base, a second base, and a temperature adjustment mechanism, the first base being provided with a scanning mechanism at least having a laser light source that emits laser light of a predetermined wavelength and a scanner that scans a scanned body by using the laser light, the second base being located at a surface of the first base opposite a surface thereof provided with the scanning mechanism and being thermally separated from the first base, the temperature adjustment mechanism being provided between the first base and the second base and adjusting a temperature of the scanning mechanism; and a microscope unit at least having a focus optical system that focuses the laser light from the scanning unit onto the scanned body placed at a predetermined position, the microscope unit being thermally separated from the scanning unit.

(12) A temperature adjustment method including:
disposing a scanning mechanism on a first base and providing a second base at a surface of the first base opposite a surface thereof provided with the scanning mechanism, the scanning mechanism at least having a laser light source that emits laser light of a predetermined wavelength and a scanner that scans a scanned body by using the laser light, the second base being thermally separated from the first base; and adjusting a temperature of the scanning mechanism by using a temperature adjustment mechanism provided between the first base and the second base.

### REFERENCE SIGNS LIST

100 scanning unit
101 scanning mechanism
103 laser light source
105 scanner
107 scan controller
111 master oscillator
113 semiconductor laser unit
115 resonator
117 optical amplifier
118 master oscillator power amplifier (MOPA)
119 wavelength converter
121 beam shape corrector
150 base plate (first base)
151 sub base plate
160 heat base (second base)
170 temperature adjustment mechanism
171 heat pipe
173 cylindrical column
180 heat discharger
181 air-cooling fan
183 heat sink
200 microscope unit
300 heat insulation wall

1. A scanning unit comprising:
a first base provided with a scanning mechanism at least having a laser light source that emits laser light of a predetermined wavelength and a scanner that scans a scanned body by using the laser light;
a second base that is located at a surface of the first base opposite a surface thereof provided with the scanning mechanism and that is thermally separated from the first base; and
a temperature adjustment mechanism that is provided between the first base and the second base and that adjusts a temperature of the scanning mechanism.

2. The scanning unit according to claim 1, wherein a surface of the second base opposite a surface thereof facing the first base is provided with a heat discharger that discharges heat discharged from the scanning mechanism by the temperature adjustment mechanism and the second base outward from the unit.

3. The scanning unit according to claim 2, wherein the heat discharger at least has an air-cooling fan that discharges the discharged heat outward from the unit.

4. The scanning unit according to claim 3,
wherein the heat discharger further has a heat sink that is disposed at the second base and that dissipates the discharged heat, and
wherein the air-cooling fan discharges the discharged heat dissipated by the heat sink outward from the unit.

5. The scanning unit according to claim 1, wherein a plurality of the temperature adjustment mechanisms are disposed in a stacked fashion in a direction extending from the first base toward the second base.

6. The scanning unit according to claim 1, wherein the scanning unit is connected to a scanned-body placement unit, in which the scanned body is placed, via a heat insulation wall composed of a predetermined heat insulation material.

7. The scanning unit according to claim 1, wherein the temperature adjustment mechanism is at least one of a Peltier element, a heat pipe, and a thermal conductive sheet.

8. The scanning unit according to claim 1, wherein the laser light source is a master oscillator having a semiconductor laser and a resonator.

9. The scanning unit according to claim 1, wherein the laser light source is a master oscillator power amplifier that includes a master oscillator and an optical amplifier, the master oscillator having a semiconductor laser and a resonator, the optical amplifier amplifying laser light from the master oscillator.

10. The scanning unit according to claim 1, wherein the laser light source is a light source that includes a master oscillator, an optical amplifier, and a wavelength converter, the master oscillator having a semiconductor laser and a resonator, the optical amplifier amplifying laser light from the master oscillator, the wavelength converter converting a wavelength of the amplified laser light.

11. A laser scanning microscope comprising:
a scanning unit that includes a first base, a second base, and a temperature adjustment mechanism, the first base being provided with a scanning mechanism at least having a laser light source that emits laser light of a predetermined wavelength and a scanner that scans a scanned body by using the laser light, the second base being located at a surface of the first base opposite a surface thereof provided with the scanning mechanism and being thermally separated from the first base, the temperature adjustment mechanism being provided between the first base and the second base and adjusting a temperature of the scanning mechanism; and
a microscope unit at least having a focus optical system that focuses the laser light from the scanning unit onto the scanned body placed at a predetermined position, the microscope unit being thermally separated from the scanning unit.

12. A temperature adjustment method comprising:
disposing a scanning mechanism on a first base and providing a second base at a surface of the first base opposite a surface thereof provided with the scanning mechanism, the scanning mechanism at least having a laser light source that emits laser light of a predetermined wavelength and a scanner that scans a scanned body by using the laser light, the second base being thermally separated from the first base; and
adjusting a temperature of the scanning mechanism by using a temperature adjustment mechanism provided between the first base and the second base.
